(19) United States
(12) Patent Application Publication
(10) Pub. No.: US 2025/0061371 A1
(43) Pub. Date: Feb. 20, 2025

(54) Method for Determining a Condition of a Quantum Computing Systems

(71) Applicant: Rohde & Schwarz GmbH & Co. KG, Muenchen (DE)

(72) Inventors: Peter John GREEN; Rajashekar DURAI; Kok Meng WONG

(73) Assignee: Rohde & Schwarz GmbH & Co. KG, Muenchen (DE)

(21) Appl. No.: 18/450,857

(22) Filed: Aug. 16, 2023

(51) Int. Cl. G06N 10/70

(52) U.S. Cl. CPC G06N 10/70; G01R 31/11

(57) ABSTRACT

A method for determining a condition of a quantum computer is described. The method includes the steps of: providing a quantum computing system having a cryogenic chamber with at least one quantum computing chip inside the cryogenic chamber, wherein the at least one quantum computing chip is connected to at least one cable running through the cryogenic chamber; performing a time-domain reflectometry measurement on the cable, thereby obtaining measurement data; and determining a condition of the quantum computing system based on the measurement data obtained from the time-domain reflectometry measurement.

### FIELD OF THE DISCLOSURE

The present disclosure relates to quantum computing systems. One aspect relates to a method for determining a condition of a quantum computing system. Another aspect relates to a method for determining reference data to be used for determining a condition of a quantum computing system.

### BACKGROUND

Superconducting quantum computers, also called quantum computing systems, use quantum computing chips (serving as quantum processors) including Josephson junctions that work at very low superconducting temperatures. The Josephson junctions perform qubit operations controlled by signals sent down via coaxial cables, e.g. from outside the cryogenic chamber (cryostat), through multiple plates positioned in the cryogenic chamber. The signals traverse regions of the chamber where the temperature decreases gradually from room temperature (300K) to near zero Kelvin to operate the quantum computing chip.

The complexities of quantum computing require robust radio frequency connectors and cable assemblies to transport qubit information reliably to and from the quantum chip. Cables must operate in extremely low temperatures and space-constricted environments. Further, no interference with applied magnetic fields shall take place.

As there are many cables and connectors operating in extreme temperatures, a fault in a cable and/or a connector may occur. Should a fault occur, a significant amount of downtime is needed to find the defective cable or connector, as the entire quantum computer has to be shut down and its components have to be analyzed individually.

Accordingly, there is a need for methods for determining a condition of a quantum computing system that address these problems.

### SUMMARY

The present disclosure provides a method for determining a condition of a quantum computing system. In an embodiment, the method comprises the steps of: providing a quantum computing system having a cryogenic chamber with at least one quantum computing chip inside the cryogenic chamber, wherein the at least one quantum computing chip is connected to at least one cable running through the cryogenic chamber, performing a time-domain reflectometry measurement on the at least one cable, thereby obtaining measurement data, and determining a condition of the quantum computing system based on the measurement data obtained from the time-domain reflectometry measurement.

The at least one cable can be connected to the quantum computing chip directly or indirectly, e.g. via another cable and/or connector(s). The quantum computing chip serves, for example, as a quantum processor. The quantum computing system may further comprise a signal generator configured for controlling a state of the quantum processor, a signal analyzer configured for reading out a state of the quantum processor, or an electronic circuit configured for both controlling and reading out a state of the quantum processor. The at least one cable may be connected to the signal generator, the signal analyzer, or the electronic circuit. The respective connection may be direct or indirect. The respective component, e.g. the signal generator, the signal analyzer or the electronic circuit, may be located outside the cryogenic chamber or inside the cryogenic chamber.

The time time-domain reflectometry measurement is generally used to determine characteristics of electrical lines (cables and/or connectors) by observing reflected signal portions, e.g. reflected pulses. Hence, a signal, e.g. a signal pulse, is sent towards the at least one cable, wherein a reflected signal portion, e.g. a reflected pulse, is received so as to gather the measurement data. Based on the measurement data, the condition of the quantum computing system can be derived. In some embodiments, the time-domain reflectometry measurement may be done by a time-domain reflectometer that comprises the signal generator and the signal analyzer. Accordingly, the electronic circuit may be the time-domain reflectometer or establish at least a part of the time-domain reflectometer.

In some embodiments, the time-domain reflectometry measurement can be performed when the quantum computing system is in its operation mode, namely cooled down. The at least one cable is located within the cooled down cryogenic chamber. Hence, downtime can be avoided for locating the failure. In addition, the downtime for fixing the failure can be reduced, as the failure is determined and located in the operation mode of the quantum computing system, namely when the cable is located within the cooled down cryogenic chamber.

In other embodiments, it is possible to perform the time-domain reflectometry measurement when the cryogenic chamber is not cooled down, for example not even closed.

In some embodiments, a cable assembly may be used within the quantum computing system, which comprises the at least one cable, for example several cables and several connectors. Thus, it is also possible to identify the component of the cable assembly, causing the failure, namely which of the several cables and/or which of the several connectors cause(s) the failure. The respective cables and/or connectors may be connected in series such that they are measured at once simultaneously. However, the cable assembly may also comprise at least two cable lines running in parallel within the cryogenic chamber. A cable line may consist of at least one cable. In some embodiments, a cable line may comprise cable(s) and/or connector(s).

Besides the fault detection, the time-domain reflectometry measurement may also provide further insights of the quantum computing system, which correspond to a condition of the quantum computing system, e.g. a leakage of the cryogenic chamber of the quantum computing system and/or a damage of the insulation like a micro crack, both causing an unintended temperature increase within the cryogenic chamber.

Accordingly, a condition of the quantum computing system may relate to a failure of a component of the quantum computing system and/or a faulty state of the quantum computing system, e.g. a temperature in the cryogenic chamber, which is different to the desired one, for example too high.

According to one aspect, the condition of the quantum computing system may be determined, for example, based on an analysis of the measurement data obtained from the time-domain reflectometry measurement. The measurement data obtained may be further processed, e.g. put in relation with each other or compared with reference data, in order to determine the respective condition. Consequently, deeper insights can be gathered by analyzing the measurement data rather than only relying on the directly measured measurement data.

The analysis may provide information about the integrity of at least one of the cable, a connector connected to the cable, a connection between the cable and the connector, and a connection between the cable and the quantum computing chip. Hence, the method can enable determining a fault in the entire quantum computing system, namely within the several different components. These components may be part of the cable assembly that comprises the at least one cable. Downtimes of the quantum computing system can thus be reduced significantly.

The analysis may provide a position of a fault along the length of the cable. Generally, the time-domain reflectometry measurement allows for exactly locating a fault along the at least one cable, the characteristics of which are determined, e.g. determining the location of the fault in length direction of the at least one cable. Knowing where exactly the fault is located in the cable may accelerate fixing the failure, as the faulty component or the faulty section is known. Moreover, knowledge about the exact location may aid in identifying a reason for the occurrence of the failure such that it can be avoided in the future. For instance, the failure occurs at an interface of the cable to a connector, which may be caused by a too high or too low torque when connecting these separately formed components.

In some embodiments, the at least one cable may pass through at least two regions within the cryogenic chamber, where the at least two regions differ in their respective temperature from each other. The different temperatures may result in different propagation velocities of at least two sections of the same cable. Alternatively, two distinct cables are connected with each other via a connector, wherein these cables are located in different regions.

In case the temperatures differ significantly, different cables might be useful that are optimized to the dedicated temperatures. The analysis, for example, takes into account the different propagation velocities that occur due to the different temperatures. However, the (expected) propagation velocity may differ from the measured one, which might hint towards a temperature failure in the cryogenic chamber. In quantum computing systems, different types of cables with different propagation velocities are used, as the cable between the (microwave) signal generator and the top of the cryogenic chamber is followed by special cables used inside the cryogenic chamber where the temperature is close to 0 K.

In conventional time-domain reflectometry for determining a cable fault, the propagation velocity of the cable must be known and inputted into a corresponding measurement device. A propagation velocity specific to one type of coaxial cable is used. However, this is only suitable for systems using one type of coaxial cable, for example a long cable connecting a transmitter/receiver to an antenna. However, in a quantum computing system with a cryogenic chamber, different types of cables with different propagation velocities are used, for example due to the different temperature regions within the cryogenic chamber. For example, there may be a cable connecting a signal generator and running through a top region of the cryogenic chamber, which is followed by special cables used deeper inside the cryogenic chamber where lower temperatures are reached. The different types of cable are used to provide best cable properties to the conditions they are exposed to, e.g. temperature.

In some embodiments, the at least two regions may differ in their respective temperature for example by at least 75%, 80%, or even 95%, but up to 250 K with respect to absolute temperatures. Regarding the absolute temperatures, the top region and the next one may have a temperature difference of 250 K, whereas the lowest region and the last but one lowest region have a temperature difference of only 80 mK. The regions may be thermally insulated from each other at least partly.

In some embodiments, a delay compensation may be applied that takes the different propagation velocities into account which occur due to the different types of cables used. In some embodiments, the delay compensation ensures to determine the accurate location of faults between the signal generator and the at least one quantum computing chip, as the delay compensation takes the different lengths and/or propagation velocities of the various types of cables into consideration for accurately determining the location of the fault.

In some embodiments, the time-domain reflectometry measurement may be performed on a cable assembly comprising the at least one cable and at least one further cable connected to the at least one cable, where the at least one cable and the at least one further cable have different propagation velocities. As mentioned above, a cable assembly may be used within the quantum computing system, wherein different cables are provided, for instance cables of different type. The cables may be connected in series. The analysis, for example, takes into account the different propagation velocities.

In some embodiments, the at least one cable and the at least one further cable may respectively be positioned in distinct regions of the quantum computing system, wherein the regions differ in their respective temperature. The regions may be thermally insulated from each other at least partly. The characteristics of the different cables may match the different temperatures occurring in the distinct regions so as to ensure proper operation of the quantum computing system.

According to another aspect, the measurement data of the time-domain reflectometry measurement may be stored, for example, in a reference database. Accordingly, the measurement data obtained may also be used to establish reference data, for instance for subsequent time-domain reflectometry measurements. In some embodiments, a temporal behavior can be analyzed provided that measurement data of several measurements performed are stored in the reference database. In addition, reference data may be obtained or updated based on current measurement data provided that it was verified that the current measurement data are not related to a failure.

In some embodiments, the condition of the quantum computing system may be determined based on a comparison of the measurement data obtained from the time-domain reflectometry measurement with reference data stored in a reference database. In case reference data is already provided, the actually obtained measurement data can be compared with the reference data in order to identify deviations that might be caused by a failure.

In some embodiments, the condition of the quantum computing system may be determined based on an evaluation of the measurement data obtained from the time-domain reflectometry measurement by using a trained artificial intelligence algorithm. Hence, correlations can be verified which were unknown so far, but identified by the trained artificial intelligence algorithm. In some embodiments, the artificial intelligence algorithm (executed on an artificial intelligence circuit, a neural network, etc.) may detect anomalies in the measurement data at an early stage, e.g. prior to impairing the operation of the quantum computing system. The quantum computing system may be used to detect, locate and advise on an anomaly, e.g. a major one or a sudden one. The respective failure may be caused by the cable, a connector or the cryogenic chamber, e.g. a temperature drop. Some anomalies, for instance micro cracks, are hard to locate by manual inspection, which however introduce interference and noise into the quantum computing system, thereby degrading the computing performance.

As discussed above, the time-domain reflectometry measurement can measure and observe properties right down to the quantum computing chip, e.g. the Josephson junction, and can thus detect any potential changes/defects of the quantum computing chip, for example in case the anomaly is not caused by the cable, any connector and the cryogenic chamber.

According to yet another aspect, a value of a phase parameter may be derived, for example, from the time-domain reflectometry measurement. The phase parameter may be, for example, a phase delay or a change of phase along the cable assembly, namely the at least one cable and/or connector(s). Since changes of the phase parameter are related to change in electrical length of the cable due to thermal expansion or contraction of the cable and the variation of the dielectric constant of the cable insulation with temperature, the measurement of these changes may be used to obtain information about a temperature inside the cryogenic chamber.

To obtain a deeper insight, an initial characterization of the quantum computing system may be performed beforehand. Additionally or alternatively, corresponding technical data about the specific cables/connectors used in the cryogenic chamber may be obtained e.g. from their respective specifications or data sheets or similar.

In this regard, the method may further comprise performing at least another time-domain reflectometry measurement on the at least one cable, wherein during the time-domain reflectometry measurements, the at least one cable is at different temperatures, respectively. The method, for example, includes deriving another value of the phase parameter of the at least one cable from measurement data obtained from the another time-domain reflectometry measurement. By obtaining measurement data of the cable at different temperatures, the behavior of the cable at different temperatures may be gathered and stored, e.g. as reference data in the reference database.

In the methods according to certain embodiments of the present disclosure, the time-domain reflectometry measurement may be performed before the cryogenic chamber is cooled down to a target temperature for operating the quantum computing system. The time-domain reflectometry measurement may be, for example, performed before the cryogenic chamber of the quantum computing system is closed or in its operation state.

In case the cryogenic chamber is cooled down to a defined temperature, the characterization of the at least one cable may be performed at this defined temperature. By performing several time-domain reflectometry measurements during the cooling down process to the target temperature for operating the quantum computing system, information about the cable (assembly) is gathered for different temperatures, namely the ones reached during the cooling down. This might help to detect a temperature increase during the operation of the quantum computing system afterwards since the behavior for higher temperatures, for example its development, has been recorded previously, for example during the cooling down process, thereby using the necessary cooling time for obtaining useful information.

In some embodiments, the time-domain reflectometry measurement is performed on several cables positioned in the cryogenic chamber, where the cables are connected to a switch box. Those cables connected to the switch box may relate to different cable lines. Hence, at least two cables are running in parallel, wherein they are connected to the switch box. All of those parallel cables can be tested effectively by using the switch box. In some embodiments, the time-domain reflectometry measurements are performed by a device connected to the switch box. Hence, it may be determined in which of the several cables a fault is located, for example in which of the cable lines and, specifically, in which particular cable of the cable line having the fault.

In some embodiments, the device may be a signal generator configured for controlling a state of the quantum computing chip, a signal analyzer configured for reading out a state of the quantum computing chip, or the electronic circuit configured for both controlling and reading out a state of the quantum computing chip. In some embodiments, the respective device may relate to the time-domain reflectometer mentioned before.

In some embodiments, the respective device may relate to a signal generator or signal analyzer having the additional functionality of performing time-domain reflectometry measurements.

Therefore, a testing device is provided that is configured to perform the method(s) of determining a condition of a quantum computing system, namely performing a time-domain reflectometry measurement on the at least one cable connected to the quantum computing chip and running through the cryogenic chamber of the quantum computing system, thereby obtaining measurement data, and determining a condition of the quantum computing system based on the measurement data obtained from the time-domain reflectometry measurement.

As mentioned above, the testing device may be a signal generator or a signal analyzer.

The present disclosure further provides a method for determining reference data to be used for determining a condition of a quantum computing system. In an embodiment, the method comprises the steps of providing a quantum computing system having a cryogenic chamber with at least one load inside the cryogenic chamber, wherein the at least one load is connected to at least one cable running through the cryogenic chamber, performing a time-domain reflectometry measurement on the cable, thereby obtaining reference data, and storing the reference data for comparison purposes in a reference database.

In some embodiments, the at least one cable is connected to the at least one load during the time domain reflectometry measurement, instead of being connected to the quantum computing chip. However, the at least one cable is connected to the quantum computing chip during the regular operation of the quantum computing system. Hence, the load replaces the quantum computing chip for determining the reference data.

In some embodiments, the reference data determined can be used to determine a condition of the quantum computing system based on (subsequently) obtained measurement data. In some embodiments, the ability to determine faults in a quantum computing system can be provided.

Different cable assemblies and/or different loads may be used for different regions in the cryogenic chamber. A cable assembly, for example, comprises one or more cables and/or connectors for interconnecting the cable, the cable with the load or other components of the quantum computing system. The different regions of the cryogenic chamber, for example, have different temperatures, respectively.

In some embodiments, an artificial intelligence algorithm may be trained on the reference data stored in the reference database. The reference data may be part of training data for the artificial intelligence algorithm. The training data may also comprise output values that are compared afterwards with the output of the artificial intelligence algorithm. In case deviations between the output and the output values of the training data take place, the artificial intelligence algorithm may be adapted, e.g. weightings of interconnected layers may be altered until the output of the artificial intelligence algorithm and the output values of the training data do not deviate from each other or the deviation is acceptable, namely below a threshold.

Of course, the testing device is also configured to perform the method(s) for determining reference data mentioned above.

The present disclosure also provides a quantum computing system. In an embodiment, the quantum computing system comprises a cryogenic chamber, at least one quantum computing chip inside the cryogenic chamber, and a cable positioned in the cryogenic chamber, wherein the cable is connected with the at least one quantum computing chip.

In some embodiments, the quantum computing system comprises at least one electronic circuit configured to perform a time-domain reflectometry measurement on the cable, and determine a condition of the quantum computing system, wherein measurement data from the time-domain reflectometry measurement is used for determining the condition.

The advantages mentioned above also apply to the quantum computing system that is configured to perform the respective method of determining a condition.

In some embodiments, the at least one electronic circuit may be separately formed with respect to the cryogenic chamber and/or integrated within a signal generator or a signal analyzer.

Generally, the electronic circuit may be a part of a (testing) device, where the quantum computing system for example includes the (testing) device. The (testing) device can be for example a signal generator configured for controlling a state of the quantum computing chip, a signal analyzer configured for reading out a state of the quantum computing chip, or an electronic circuit configured for both controlling and reading out a state of the quantum computing chip.

In some embodiments, the quantum computing system may comprise an electrical connector for connecting several cables. The several cables may have different propagation velocities.

Generally, the time-domain reflectometry measurement can be performed on a cable assembly having several cables, for example several different cable types. When having the reference database, knowledge about the behavior of these different cables, for example at different temperatures, is available which can be used for determining a condition of the quantum computing system, e.g. determining a temperature within the cryogenic chamber (at a certain location) or identifying a failure. In some embodiments, the signal generator used for exciting the at least one quantum computing chip can also be used for performing the time-domain reflectometry measurement. Hence, the number of devices and components can be reduced, thereby reducing the overall costs.

Consequently, the method(s) and the quantum computing system(s) (as well as the testing device) ensure to use time-domain reflectometry method for determining a fault in a cable assembly used in the quantum computing system.

Moreover, it is ensured that every connection at every level is previously characterized in order to obtain signatures for each cable and/or each interface (connector) used in the cable assembly. Based on these signatures, anomalies can be detected earlier and faults can be located more precisely.

In addition, different cable types are taken into consideration in order to compensate for different delays introduced by the types of cables used in the cable assembly.

Furthermore, the time-domain reflectometry method(s) can also be used to determine a temperature in the cryogenic chamber while assuming the cable assembly, for example the at least one cable, being free from failures.

Additionally, a trained artificial intelligence algorithm may be applied on the measurement data obtained for predictive maintenance and anomaly detection. In these embodiments, the artificial intelligence algorithm is trained based on the reference data mentioned above, thereby learning valid data of the time-domain measurements. The artificial intelligence algorithm is trained to detect anomalies and/or failures in the quantum computing system, e.g. deterioration of the thermal insulation, aging effects of seals and connections or micro cracks.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 is a schematic view of a quantum computing system according to an embodiment of the present disclosure;

FIG. 2 is a schematic view of a quantum computing system according to another embodiment of the present disclosure;

FIG. 3 is a schematic view of a quantum computing system according to still another embodiment of the present disclosure;

FIG. 4 is a schematic view of a quantum computing system according to yet another embodiment of the present disclosure;

FIG. 5 is a flowchart illustrating a representative method for determining a condition of a quantum computing system according to an embodiment of the present disclosure;

FIG. 6 is a flowchart illustrating a representative method for determining a condition of a quantum computing system according to another embodiment of the present disclosure;

FIG. 7 is a schematic view of a quantum computing system according to an embodiment of the present disclosure; and

FIG. 8 is a flowchart illustrating a representative method for determining reference data to be used for determining a condition of a quantum computing system according to an embodiment of the present disclosure.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

Similarly, any steps described herein may be interchangeable with other steps, or combinations of steps, in order to achieve the same or substantially similar result. Moreover, some of the method steps can be carried serially or in parallel, or in any order unless specifically expressed or understood in the context of other method steps.

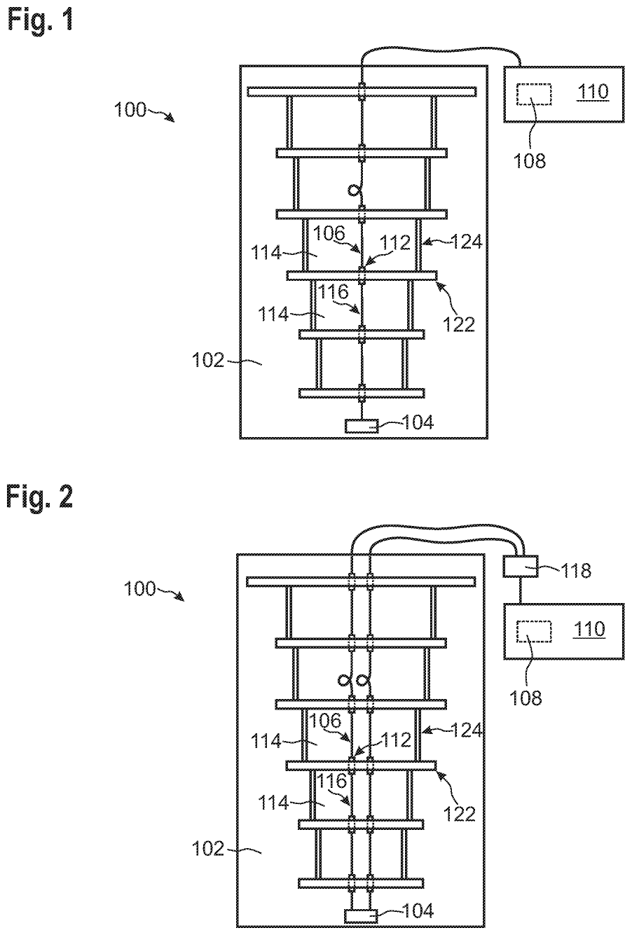

FIG. 1 is a schematic view of a quantum computing system 100 according to an embodiment of the present disclosure. The quantum computing system 100 comprises a cryogenic chamber 102 and at least one quantum computing chip 104 inside the cryogenic chamber 102.

In the embodiment shown, the quantum computing system 100 further comprises a cable 106 positioned in the cryogenic chamber 102. The cable 106 is connected with the at least one quantum computing chip 104. The cable 106 may be connected with the quantum computing chip 104 indirectly, as shown in the depicted embodiment.

In some embodiments, the quantum computing system 100 may further comprise plates 122 positioned within the cryogenic chamber 102. The plates 122, for example, separate regions 114 within the cryogenic chamber 102. The plates 122 may be connected via support posts 124.

In an operating state of the quantum computing system 100, the plates 122 may be held at different temperatures, respectively, such that corresponding regions 114 are associated with different temperatures. In some embodiments, the respective plate 122 is held at a colder temperature the closer it is positioned to the quantum computing chip 104. Hence, the region 114 is the coldest in which the quantum computing chip 104 is located. As a consequence, a temperature inside the cryogenic chamber 102 decreases towards the quantum computing chip 104.

In some embodiments, the quantum computing system 100 comprises at least one electronic circuit 108 configured for performing a time-domain reflectometry measurement on the cable 106. The electronic circuit 108 may be further configured for determining a condition of the quantum computing system 100, namely based on measurement data obtained from the first time-domain reflectometry measurement. Accordingly, the electronic circuit 108 may relate to a signal analyzer.

As shown in the depicted embodiment, the at least one electronic circuit 108 may be separately formed with respect to the cryogenic chamber 102. The electronic circuit 108 may be integrated within a signal generator or a signal analyzer.

In some embodiments, the electronic circuit 108 may be a part of a device 110. The quantum computing system 100, for example, includes the device 110. The device 110 can be for example a signal generator configured for controlling a state of the quantum computing chip 104, a signal analyzer configured for reading out a state of the quantum computing chip 104, or a (test) instrument configured for both controlling and reading out a state of the quantum computing chip 104.

Generally, the electronic circuit 108, for example the signal generator, used for performing the time-domain reflectometry measurement may also be used for exciting the at least one quantum computing chip 104 during operation, e.g. controlling a state of the quantum computing chip 104.

In case the electronic circuit 108 is enabled to perform both tasks, namely performing the time-domain reflectometry measurement and determining the condition of the quantum computing system 100, the electronic circuit 108 may be at least part of a time-domain reflectometer.

In some embodiments, the quantum computing system 100 may further comprise an electrical connector 112 for connecting several cables, for example cables of different types. Thus, the several cables may have different propagation velocities. For example, the further cable 116 may have a different propagation velocity than the cable 106.

As depicted in FIGS. 1 and 2, the quantum computing chip 104 may be connected (directly or indirectly) to a plurality of cables 106, namely several cables 106 connected in series (FIG. 1) or several cables 106 connected in series and in parallel to each other, thereby establishing two cable lines. Generally, the cable(s) 106 and/or connector(s) relate to a cable assembly that is used for operating the quantum computing chip 104.

The cables 106, for example the different cable lines, may be connected to a switch box 118. In some embodiments, the device 110 comprising the electronic circuit 108 is also connected to the switch box 118. Hence, measurements on each of the plurality of cables 106, for example the cable lines running in parallel, can be performed sequentially via the device 110.

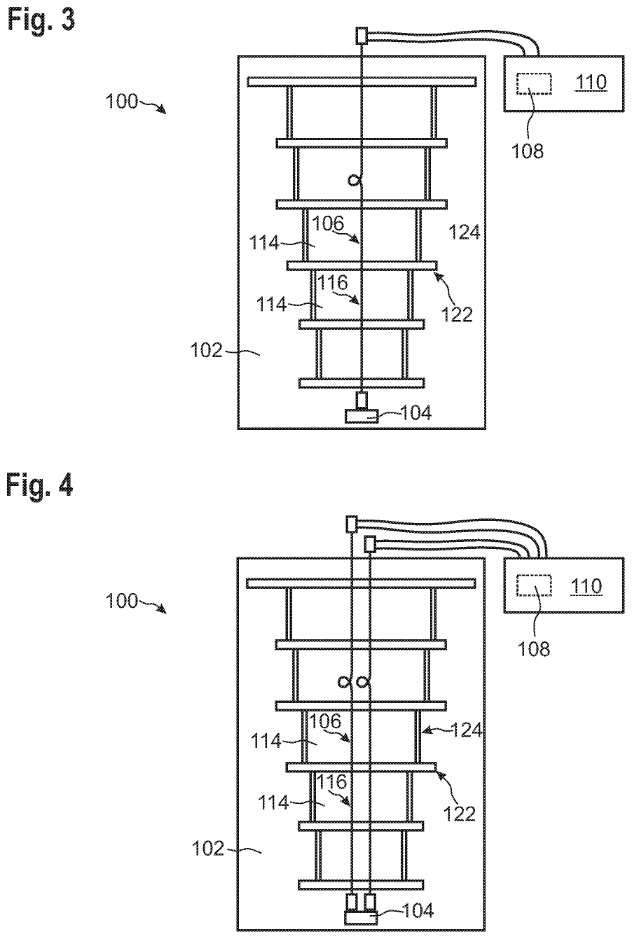

Referring now to FIG. 3, the at least one cable 106 connected to the quantum computer chip 104 may be a multichannel cable. In some embodiments, a multichannel cable is adapted to provide a plurality of transmission lines in a single cable. Hence, a quantum computing chip 104 comprising a plurality of qubits (e.g. 4 or 8 qubits) can be controlled via the single cable 106.

A further multichannel cable can be connected to the quantum computing chip 104, as shown in FIG. 4. As an example, one of the multichannel cables can be used for controlling a plurality of qubits of the quantum computing chip 104 and the other one may be before reading out the state of the qubits.

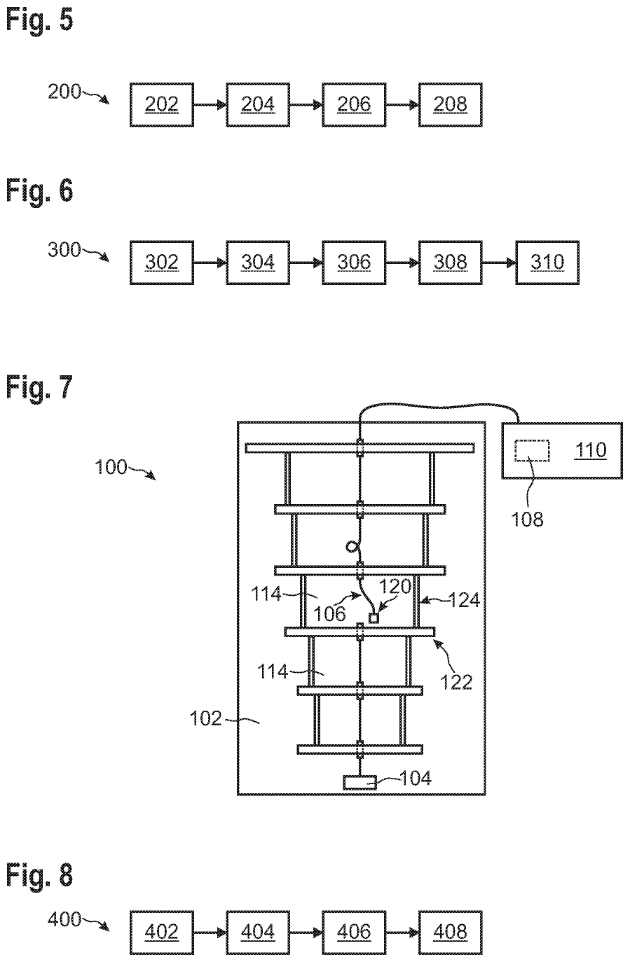

FIG. 5 is a flowchart illustrating a method 200 for determining a condition of a quantum computing system 100 according to an embodiment of the present disclosure, for example one of the quantum computing systems 100 shown in FIGS. 1 to 4.

The method 200 comprises a step 202 of providing the quantum computing system 100 having the cryogenic chamber 102 with the at least one quantum computing chip 104 inside the cryogenic chamber 102. The at least one quantum computing chip 104 is connected to the at least one cable 106 running through the cryogenic chamber 102.

The method 200 further comprises a step 204 of performing a time-domain reflectometry measurement on the cable 106, thereby obtaining measurement data. The respective time-domain reflectometry measurement is done by a signal generator and a signal analyzer or an electronic circuit 108 (test instrument having the electronic circuit 108).

In addition, the method 200 comprises a step 206 of determining a condition of the quantum computing system 100 based on the measurement data obtained from the time-domain reflectometry measurement. This may be done by the signal analyzer or the electronic circuit 108. As discussed above, the electronic circuit 108 may be part of a device 110, e.g. a testing device, a signal generator or a signal analyzer.

The condition of the quantum computing system 100 may be determined based on an analysis of the measurement data obtained from the time-domain reflectometry measurement. In some embodiments, the analysis may provide information about the integrity of the at least one cable 106, the at least one connector 112 connected to the cable 106, a connection between the cable 106 and the connector 112, and a connection between the cable 106 and/or the quantum computing chip 104. Generally, each component of the cable assembly used for connecting the quantum computing chip 104 for operating purposes may be analyzed. Hence, the method 200 can enable determining a fault in the entire quantum computing system 100. Downtimes of the quantum computing system 100 can thus be reduced significantly.

In some embodiments, the analysis may provide a position of a fault along the length of the at least one cable 106 as shown in FIG. 3. In case of several cables 106, 116 being connected in series with each other (FIGS. 1 and 2), the analysis may still exactly locate the fault in the cable line comprising the different cables 106, 116. In case of several cables 106, 116 being located in parallel (FIGS. 2 and 4), the analysis still exactly locate the fault, namely the respective signal line and more specifically the faulty cable 106, 116 in the cable line. Knowing where exactly the fault is located may accelerate the fixing of the failure.

This can be achieved since the at least one cable 106, 116, for example the entire cable assembly, passes through at least two regions 114 within the cryogenic chamber 102. The at least two regions 114 may differ in their respective temperature from each other, resulting in different propagation velocities of at least two sections of the single cable 106. The analysis, for example, takes into account the different propagation velocities due to the temperature.

In case of several cables 106, 116 connected in series, for example cables 106, 116 of different type having different properties like different propagation velocities, these different properties are also taken into consideration. In this scenario, information about the different types may be stored, for instance by means of reference data. The reference data may be obtained by performing reference measurements (calibrations) or from data sheets and/or specifications of the cables 106, 116.

In some embodiments, radio frequency cables for superconducting applications are typically constructed using a silicon dioxide (SiO2) dielectric. This type of cable works at temperatures ranging from just above absolute zero to 1000° C. For quantum computing applications, new outer conductors of the coaxial cables are typically used. A Copper-Nickel (CuNi)-based semi-rigid construction may be used from room temperature to about 4K and a Niobium-Titanium (NbTi) construction from 4K down to 4 mK. The NbTi is a superconducting cable that is designed to interface with the quantum processor directly. Thus, to ensure accurate location of cable/connector faults between a signal generator and the quantum computing chip 104, the lengths and propagation velocities of the various types of cables have to be taken into consideration.

In some embodiments, the at least two regions 114, which are associated with the sections of the single cable 106 or associated with the separate cables 106, 116 connected with each other in series, may differ in their respective temperature by for example at least 10%, 20% or 30%. The regions 114 may be thermally insulated from each other at least partly.

In some embodiments, the time-domain reflectometry measurement may be performed on a cable assembly comprising the at least one cable 106 and the at least one further cable 116 connected to the cable 106, wherein the cable 106 and the at least one further cable 116 have different propagation velocities. The analysis, for example, takes into account the different propagation velocities as discussed above. Hence, the time-domain reflectometry measurement may be performed on several cables 106, 116 positioned in the cryogenic chamber 102, wherein the cables 106, 116 may run in parallel. Hence, these cables 106, 116 are connected to the switch box 118 to which the (testing) device 110 is connected. By the switch box 118, the different cable lines running in parallel can be connected to the (testing) device 110 such that a signal (pulse) is sent towards the quantum computing chip 104 and the reflected signal (pulse) is received.

The cable 106 and the at least one further cable 116 may be positioned in distinct regions 114 of the quantum computing system 100, respectively. In some embodiments, the regions 114 differ in their respective temperature. The regions 114 may be thermally insulated from each other at least partly.

In some embodiments, the time-domain reflectometry measurement may be performed before the cryogenic chamber 102 is closed and/or cooled down to a target temperature for operating the quantum computing system 100. In some embodiments, the time-domain reflectometry measurement can be performed before the cryogenic chamber 102 is closed.

FIG. 6 is a flowchart illustrating a method 300 for determining condition of a quantum computing system 100 according to an embodiment of the present disclosure. As already discussed above, the method 300 comprises a step 302 of providing the quantum computing system 100 and a step 304 of performing a time-domain reflectometry measurement on the at least one cable 106, thereby obtaining measurement data.

In addition, the method 300 comprises a step 306 of deriving a value of a phase parameter from the time-domain reflectometry measurement. The phase parameter may be, for example, a phase delay or a variation of the delay.

For instance, the temperature within the cryogenic chamber 102 can be determined, as it is assumed that the cable assembly, namely the at least one 106, the at least one further cable 116 and the connectors 112 have no faults.

In some embodiments, the phase change properties of the at least one cable 106, for example the cable assembly, over temperature are related to the change in electrical length due to thermal expansion or contraction of the materials and the variation of the dielectric constant of the insulation with temperature.

In some embodiments, the method 300 may further comprise a step 308 of performing at least another time-domain reflectometry measurement on the at least one cable 106, for example the entire cable assembly, wherein during the time-domain reflectometry measurements, the at least one cable 106 is at different temperatures, respectively. Moreover, the method 300 may comprise a step 310 of deriving another value of the phase parameter of the at least one cable 106 from measurement data obtained from the another time-domain reflectometry measurement.

Hence, information of the at least one cable 106 at different temperatures are obtained, which can be used for analysis purposes as discussed hereinafter.

In some embodiments, the method 200 may further comprise a step 208 of storing the measurement data of the time-domain reflectometry measurement in a reference database. The reference database may be located in the device 110.

Accordingly, a time-domain reflectometry measurement being indicative of no fault may be used for updating the reference database or to establish a temporal evolution of measurement data, thereby obtaining information used for identifying an aging or upcoming failures.

The reference database may also comprise reference data obtained from initial measurements or reference data inputted from data sheets or specifications. Hence, the condition of the quantum computing system 100 may be determined based on a comparison of the measurement data recently obtained from the time-domain reflectometry measurement with the reference data stored in the reference database.

The reference data may be gathered as discussed hereinafter with reference to FIGS. 7 and 8. FIG. 7 is a schematic view of a quantum computing system 100 according to an embodiment of the present disclosure. The quantum computing system 100 is depicted in a state for determining reference data to be used for determining reference data. As shown, the cable 106 may be terminated by a load 120 instead of the quantum computing chip 104.

FIG. 8 is a flowchart illustrating a method 400 for determining reference data to be used for determining a condition of a quantum computing system 100 100 according to an embodiment of the present disclosure.

The method 400 comprises a step 402 of providing a quantum computing system 100 having a cryogenic chamber 102 with at least one load 120 inside the cryogenic chamber 102. The at least one load 120 is connected to at least one cable 106 running through the cryogenic chamber 102. Thus, the quantum computing system 100 corresponds to the ones shown in FIGS. 1 to 4 except for the load 120 replacing the quantum computing chip 104.

In some embodiments, the at least one cable 106 is connected to the at least one load 120 during the time domain reflectometry measurement, instead of being connected to the quantum computing chip 104.

The method 400 further comprises a step 404 of performing a time-domain reflectometry measurement on the cable 106, thereby obtaining reference data for the specific scenario, namely cable 106 and load 120.

Different cable assemblies (as well as different loads 120) may be used for different regions 114 in the cryogenic chamber 102. Accordingly, signatures for all components of the quantum computing system 100 may be gathered, namely all components of the cable assembly. In some embodiments, signatures for every connection/connector combination can be obtained.

For instance, a termination of 50 ohm loads may be used at the first thermal level, e.g. the op region 114. Then, the load is moved progressively downwardly into the cryogenic chamber 102, namely the colder regions 114.

In some embodiments, the different regions 114 of the cryogenic chamber 102, for example, differ in their temperature.

By this method, a collection of reference data is gathered for being used in the reference database. Hence, any future anomaly due to faults at cables 106, 116 and/or connectors 112 or any cable connection errors can be quickly identified, as signatures every connection/connector combination are gathered and stored in the reference database.

Hence, the method 400, in some embodiments, comprises a step 406 of storing the reference data for comparison purposes in the reference database.

As discussed, the reference data can be used to determine a condition of the quantum computing system 100 based on (subsequently) obtained measurement data. In particular, the ability to determine faults in a quantum computing system 100 can be provided.

The method 400 may further comprise a step 408 of training an artificial intelligence algorithm on the reference data stored in the reference database. The artificial intelligence algorithm may be executed on the device 110 or the electronic circuit 108. In some embodiments, the artificial intelligence algorithm is trained by the reference data in order to detect anomalies, deteriorations or aging effects. Based on the reference data, the artificial intelligence algorithm learns the properly functioning quantum computing system 100 in order to identify deviations therefrom.

Consequently, the condition of the quantum computing system 100 may be determined based on an evaluation of the measurement data obtained from the time-domain reflectometry measurement by using the trained artificial intelligence algorithm, e.g. when executed on the device 110 or the electronic circuit 108. Hence, predictive maintenance can be performed and anomalies caused by cables/connectors/cryostat temperature faults can be detected and located accurately.

Generally, the time-domain reflectometry measurement ensures to locate faults such like micro cracks that may introduce interference and noise into the quantum computing system 100, which degrades the (qubit) computing performance of the at least one quantum computing chip 104, e.g. the Josephson junction(s). By the time-domain reflectometry measurement, it is possible to observe properties right down to the at least one quantum computing chip 104, e.g. Josephson junction, and thus detect any potential changes/defects if the anomaly is not caused by the cable assembly, namely the cable(s) 106, 116 and/or the connector(s) 112.

Certain embodiments disclosed herein include components, such as for example the electronic circuit 108, the device 110, etc., that utilize circuitry (e.g., one or more circuits) in order to implement protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph. It will be further appreciated that the terms “circuitry.” “circuit,” “one or more circuits,” etc., can be used synonymously herein.

In an embodiment, circuitry includes, among other things, one or more computing devices such as a processor (e.g., a microprocessor), a central processing unit (CPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof.

In an embodiment, circuitry includes hardware circuit implementations (e.g., implementations in analog circuitry, implementations in digital circuitry, and the like, and combinations thereof). In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

In some embodiments, one or more of the components referenced above include circuitry programmed to carry out one or more steps of any of the methods disclosed herein. In some embodiments, one or more computer-readable media associated with or accessible by such circuitry contains computer readable instructions embodied thereon that, when executed by such circuitry, cause the component or circuitry to perform one or more steps of any of the methods disclosed herein.

Various embodiments of the present disclosure or the functionality thereof may be implemented in various ways, including as non-transitory computer program products. A computer program product may include a non-transitory computer-readable storage medium storing applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably). Such non-transitory computer-readable storage media include all computer-readable media (including volatile and non-volatile media).

Embodiments of the present disclosure may also take the form of an apparatus, system, computing device, computing entity, and/or the like executing instructions stored on computer-readable storage media to perform certain steps or operations. The computer-readable media include cooperating or interconnected computer-readable media, which exist exclusively on a processing or processor system or distributed among multiple interconnected processing or processor systems that may be local to, or remote from, the processing or processor system. However, embodiments of the present disclosure may also take the form of an entirely hardware embodiment performing certain steps or operations.

Various embodiments are described above with reference to block diagrams and/or flowchart illustrations of apparatuses, methods, systems, and/or computer program instructions or program products. It should be understood that each block of any of the block diagrams and/or flowchart illustrations, respectively, or portions thereof, may be implemented in part by computer program instructions, e.g., as logical steps or operations executing on one or more computing devices. These computer program instructions may be loaded onto one or more computer or computing devices, such as special purpose computer(s) or computing device(s) or other programmable data processing apparatus(es) to produce a specifically-configured machine, such that the instructions which execute on one or more computer or computing devices or other programmable data processing apparatus implement the functions specified in the flowchart block or blocks and/or carry out the methods described herein.

These computer program instructions may also be stored in one or more computer-readable memory or portions thereof, such as the computer-readable storage media described above, that can direct one or more computers or computing devices or other programmable data processing apparatus(es) to function in a particular manner, such that the instructions stored in the computer-readable memory produce an article of manufacture including computer-readable instructions for implementing the functionality specified in the flowchart block or blocks.

The computer program instructions may also be loaded onto one or more computers or computing devices or other programmable data processing apparatus(es) to cause a series of operational steps to be performed on the one or more computers or computing devices or other programmable data processing apparatus(es) to produce a computer-implemented process such that the instructions that execute on the one or more computers or computing devices or other programmable data processing apparatus(es) provide operations for implementing the functions specified in the flowchart block or blocks and/or carry out the methods described herein.

It will be appreciated that the term computer or computing device can include, for example, any computing device or processing structure, including but not limited to a processor (e.g., a microprocessor), a central processing unit (CPU), a graphical processing unit (GPU), a digital signal processor (DSP), an application-specific integrated circuit (ASIC), a field-programmable gate array (FPGA), a system on a chip (SoC), or the like, or any combinations thereof.

Accordingly, blocks of the block diagrams and/or flowchart illustrations support various combinations for performing the specified functions, combinations of operations for performing the specified functions and program instructions for performing the specified functions. Again, it should also be understood that each block of the block diagrams and flowchart illustrations, and combinations of blocks in the block diagrams and/or flowchart illustrations, or portions thereof, could be implemented by special purpose hardware-based computer systems or circuits, etc., that perform the specified functions or operations, or combinations of special purpose hardware and computer instructions.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

The embodiments of the invention in which an exclusive property or privilege is claimed are defined as follows:

1. A method for determining a condition of a quantum computing system, the method comprising the steps of:
providing a quantum computing system having a cryogenic chamber with at least one quantum computing chip inside the cryogenic chamber, wherein the at least one quantum computing chip is connected to at least one cable running through the cryogenic chamber,
performing a time-domain reflectometry measurement on the at least one cable, thereby obtaining measurement data, and
determining a condition of the quantum computing system based on the measurement data obtained from the time-domain reflectometry measurement.

2. The method according to claim 1, wherein the condition of the quantum computing system is determined based on an analysis of the measurement data obtained from the time-domain reflectometry measurement.

3. The method according to claim 2, wherein the analysis provides information about the integrity of at least one of the cable, a connector connected to the cable, a connection between the cable and the connector, and a connection between the cable and the quantum computing chip.

4. The method according to claim 2, wherein the analysis provides a position of a fault along the length of the at least one cable.

5. The method according to claim 2, wherein the at least one cable passes through at least two regions within the cryogenic chamber, the at least two regions differing in their respective temperature from each other, resulting in different propagation velocities of at least two sections of the at least one cable, and wherein the analysis takes into account the different propagation velocities.

6. The method according to claim 2, wherein the time-domain reflectometry measurement is performed on a cable assembly comprising the at least one cable and at least one further cable connected to the at least one cable, wherein the at least one cable and the at least one further cable have different propagation velocities, and wherein the analysis takes into account the different propagation velocities.

7. The method according to claim 6, wherein the at least one cable and the at least one further cable are respectively positioned in distinct regions of the quantum computing system and wherein the regions differ in their respective temperature.

8. The method according to claim 1, wherein the measurement data of the time-domain reflectometry measurement is stored in a reference database.

9. The method according to claim 1, wherein the condition of the quantum computing system is determined based on a comparison of the measurement data obtained from the time-domain reflectometry measurement with reference data stored in a reference database.

10. The method according to claim 1, wherein the condition of the quantum computing system is determined based on an evaluation of the measurement data obtained from the time-domain reflectometry measurement by using a trained artificial intelligence algorithm.

11. The method according to claim 1, wherein a value of a phase parameter is derived from the time-domain reflectometry measurement.

12. The method according to claim 11, wherein the method further comprises the steps of:
performing at least another time-domain reflectometry measurement on the at least one cable, wherein during the time-domain reflectometry measurements, the at least one cable is at different temperatures, respectively, and
deriving another value of the phase parameter of the cable from measurement data obtained from the another time-domain reflectometry measurement.

13. The method according to claim 1, wherein the time-domain reflectometry measurement is performed before the cryogenic chamber is cooled down to a target temperature for operating the quantum computing system.

14. The method according to claim 1, wherein the time-domain reflectometry measurement is performed on several cables positioned in the cryogenic chamber, wherein the cables are connected to a switch box, and wherein the time-domain reflectometry measurements are performed by a device connected to the switch box.

15. A method for determining reference data to be used for determining a condition of a quantum computing system, the method comprising the steps of:
providing a quantum computing system having a cryogenic chamber with at least one load inside the cryogenic chamber, wherein the at least one load is connected to at least one cable running through the cryogenic chamber,
performing a time-domain reflectometry measurement on the cable, thereby obtaining reference data, and
storing the reference data for comparison purposes in a reference database.

16. The method according to claim 15, wherein at least one of different cable assemblies or different loads for different regions in the cryogenic chamber are used.

17. The method according to claim 15, wherein an artificial intelligence algorithm is trained on the reference data stored in the reference database.

18. A quantum computing system comprising:
a cryogenic chamber;
at least one quantum computing chip inside the cryogenic chamber; and
a cable positioned in the cryogenic chamber, wherein the cable is connected with the at least one quantum computing chip,
wherein the quantum computing system comprises at least one electronic circuit configured to:
perform a time-domain reflectometry measurement on the cable, and
determine a condition of the quantum computing system, wherein measurement data from the time-domain reflectometry measurement is used for determining the condition.

19. The quantum computing system according to claim 18, wherein the at least one electronic circuit is at least one of separately formed with respect to the cryogenic chamber or integrated within a signal generator or a signal analyzer.

20. The quantum computing system according to claim 18, wherein the quantum computing system comprises an electrical connector for connecting several cables, wherein the several cables have different propagation velocities.
